(19) United States
(12) Patent Application Publication
(10) Pub. No.: US 2010/0155924 A1
(43) Pub. Date: Jun. 24, 2010

(54) SEMICONDUCTOR MODULE

(75) Inventors: Wolfgang Knapp, Lenzburg (CH); Christoph Häderli, Zurich (CH)

Correspondence Address: BUCHANAN, INGERSOLL & ROONEY PC, POST OFFICE BOX 1404, ALEXANDRIA, VA, 22313-1404, US

(73) Assignee: ABB Research Ltd, Zurich (CH)

(21) Appl. No.: 12/488,196

(22) Filed: Jun. 19, 2009

Related U.S. Application Data
(63) Continuation of application No. PCT/CH2006/000724, filed on Dec. 21, 2006.

(51) Int. Cl. H01L 23/48; H01L 23/34

(52) U.S. Cl. 257/690; 257/712; 257/E23.08; 257/E23.01

(57) ABSTRACT

A semiconductor module includes first and second sub-units, each including at least one semiconductor chip, a first contact element having a first contact side, and a second or third contact element having a second or third contact side, respectively. The semiconductor chip has opposing first and second main electrode sides. The first main electrode side of the chip is thermally connected to the first contact side, and the second main electrode side is thermally connected to the second or third contact side. In the first sub-unit, a first fixation means connects the first and second contact elements and the chip together. In the second sub-unit, a second fixation means connects the first and third contact elements and the chip together. A flexible element, which is arranged between the first contact element and the first contact element, is electrically and thermally connected to the first contact elements.

### RELATED APPLICATION

This application claims priority as a continuation application under 35 U.S.C. §120 to PCT/CH2006/00724 filed as an International Application on Dec. 21, 2006 and designating the U.S., the entire content of which are hereby incorporated by reference in its entirety.

### FIELD

The present disclosure relates to the field of high power electronics to a semiconductor module that can be utilized in the field of high power electronics.

### BACKGROUND INFORMATION

EP 1672692 shows a semiconductor module with a housing, in which two semiconductor chips are arranged. The chips are electrically and thermally contacted on their respective main electrode sides with base plates. Each base plate is in thermal contact with a cooling plate. On one side, the cooling plates of the two chips are formed as separate plates, whereas on the other side, the cooling plates of the two chips are formed as a common cooling plate with a diminution in the area between the two chips. On each side, the cooling plates prop against a half shell of a housing by the insertion of cooling fins between the cooling plate and each half shell. Compressible elements like rubber foam are arranged between the cooling fins and each half shell. The module is compressed by screws, which press both half shells with the chips, base plates, cooling plates and cooling fins in between. Due to the diminutions between the chips and the rubber foam, differences in height of the staples comprising a chip and base plates on both sides of the chip can be balanced. Such a module can also be built up with more than two chips. In any case, all chips are compressed together within the same housing by the same compression means.

### SUMMARY

At least one exemplary embodiment provides a semiconductor module comprising a first sub-unit. The first sub-unit includes a first contact element having a cooling function and a first contact side, a second contact element having a cooling function and comprising a second contact side, at least one semiconductor chip having a first main electrode side and a second main electrode side opposite to the first main electrode side, and a first fixation means for firmly connecting together the first and second contact elements of the first sub-unit and the at least one semiconductor chip of the first sub-unit. The at least one semiconductor chip of the first sub-unit is thermally connected to the first contact side on the first main electrode side of the at least one semiconductor chip of the first sub-unit, respectively. The at least one semiconductor chip of the first sub-unit is thermally connected to the second contact side on the second main electrode side of the at least one semiconductor chip of the first sub-unit, respectively. At least one electrical connection is established between at least one semiconductor chip of the first sub-unit and the first or second contact side.

The exemplary semiconductor module also comprises a second sub-unit. The second sub-unit includes a first contact element having a cooling function and a first contact side, a third contact element having a cooling function and a third contact side, at least one semiconductor chip having a first main electrode side and a second main electrode side opposite to the first main electrode side, and a second fixation means for firmly connecting together the first and third contact elements of the second sub-unit and the at least one semiconductor chip of the second sub-unit. The at least one semiconductor chip of the second sub-unit is thermally connected to the first contact side of the second unit on the first main electrode side of the at least one semiconductor chip of the second sub-unit, respectively. The at least one semiconductor chip of the second sub-unit is thermally connected to the third contact side on the second main electrode side of the second sub-unit. At least one electrical connection is established between at least one semiconductor chip of the second sub-unit and the first or third contact side of the second sub-unit.

The exemplary semiconductor module additionally comprises at least one first flexible element, which is arranged between the first contact element of the first sub-unit and the first contact element of the second sub-unit. At least one first flexible element is electrically and thermally connected to the first contact element of the first sub-unit and to the first contact element of the second sub-unit. The first sub-unit and the second sub-unit are individually compressed by the first fixation means and the second fixation means, respectively.

An exemplary embodiment of the present disclosure provides a semiconductor module comprising a first sub-unit including a first contact element having a first contact side, a second contact element having a second contact side, at least one semiconductor chip having a first main electrode side and a second main electrode side opposite to the first main electrode side, and a first fixation means for firmly connecting together the first and second contact elements of the first sub-unit and the at least one semiconductor chip of the first sub-unit. The exemplary semiconductor module also comprises a second sub-unit including a first contact element having a first contact side, a third contact element having a third contact side, at least one semiconductor chip having a first main electrode side and a second main electrode side opposite to the first main electrode side, and a second fixation means for firmly connecting together the first and third contact elements of the second sub-unit and the at least one semiconductor chip of the second sub-unit. In addition, the exemplary semiconductor module comprises at least one first flexible element, which is arranged between the first contact element of the first sub-unit and the first contact element of the second sub-unit. At least one of the at least one first flexible element is electrically and thermally connected to the first contact element of the first sub-unit and to the first contact element of the second sub-unit. The first sub-unit and the second sub-unit are individually compressed by the first fixation means and the second fixation means, respectively.

In accordance with the above-described exemplary embodiments, the chips can be arranged in a plane, so that the space in both directions vertical to the main electrode sides of the chips can be used for cooling purposes. Accordingly, an efficient two sided-cooling can be achieved. As the contact elements are connected to the chips on both main electrode sides of the chips, heat produced in the chips can be dissipated over a great surface and over short distances to the contact elements.

Since each sub-unit has its own individual fixation means, differences in height between the staples of two sub-units can be easily compensated. Besides, the sub-units comprising one or more semiconductor chips can easily be pre-mounted from one side. Therefore, the manufacturing of the module is easy.

There is no necessity for a housing for fixation purposes of the exemplary module. The module with the semiconductor chips sandwiched between the contact elements is a mechanically stable unit even without such a housing. The contact elements, which can be in contact with cooling fins, can also be used with any fluid (gas like air or liquid like water) for an improved cooling.

By connecting two neighboured sub-units mechanically on one side by a first flexible element, which electrically and thermally contacts the two contact elements, a robust electrical connection can be achieved and the semiconductor module is suitable for high currents.

### BRIEF DESCRIPTION OF THE DRAWINGS

Further advantages and refinements of the present disclosure are explained in more detail below with reference to exemplary embodiments which are illustrated in the attached drawings, in which:

FIG. 1 shows a cross sectional view of an exemplary semiconductor subassembly according to at least one embodiment;

FIG. 2 shows a perspective view of an exemplary two-level-three-phase inverter according to at least one embodiment;

FIG. 3 shows a top view of an exemplary two-level-three-phase inverter according to at least one embodiment;

FIG. 4 shows a schematic diagram of an exemplary two-level-three-phase inverter according to at least one embodiment; and

FIG. 5 shows a perspective view on another embodiment of a first sub-module according to at least one embodiment.

Elements denoted with reference symbols in the drawings and are summarized in the list of reference symbols. Generally, the same or similarly-functioning elements are given the same reference symbols. The exemplary embodiments as described herein are meant as examples and shall not confine the invention as claimed.

### DETAILED DESCRIPTION

An exemplary embodiment of the present disclosure provides a semiconductor module with semiconductor chips, in which sub-units, which can each have at least one semiconductor chip, can be individually compressed. In addition, the sub-units can be efficiently cooled and good electrical connections can be provided between the sub-units.

FIG. 1 illustrates an exemplary semiconductor module 1 according to at least one embodiment of the present disclosure. The exemplary semiconductor module 1 can comprise a first sub-unit 11 with a first contact element 31 having a cooling function. The first contact element 31 can comprise a first contact side 32. The first sub-unit 11 can also comprise a second contact element 41 having a cooling function. The second contact element 41 can comprise a second contact side 42. The first sub-unit 11 can further comprise a first fixation means 6 and at least one semiconductor chip 2. The at least one semiconductor chip 2 has a first main electrode side 21 and a second main electrode side 22 opposite the first main electrode side 21. The at least one semiconductor chip 2 can be thermally connected on its first main electrode side 21 to the first contact side 32, and be thermally connected on its second main electrode side 22 to the second contact side 42. The first and second contact elements 31, 41 and the semiconductor chip(s) 2 can be firmly connected together by the first fixation means 6. At least one electrical connection can be established between at least one semiconductor chip 2 and the first or second contact side 32, 42. In the example of FIG. 1, the chip 2 is electrically connected to the first contact 32 side via an electrically conductive base plate 23, which is arranged between the chip 2 and the first contact element 31, and the chip 2 is electrically connected to the second contact 42 side via an electrically conductive base plate 24, which is arranged between the chip 2 and the second contact element 41. The first fixation means 6 can be a screw or a clamping device, for example. Springs or other types of flexible or compressible elements can be used to improve the contact between the contact elements 31, 41, base plates 23, 24 and the chip 2.

It is also possible that at least one, but not all chips 2 are electrically connected on the first main side 21 to the first contact side 32 and/or at least one, but not all chips 2 are electrically connected on the second main electrode side 22 to the second contact side 42. Any conceivable combinations of electrical connections such as all chips 2 of the first sub-unit 11 being electrically connected to the first and/or second contact side 32, 42, for example, are also possible.

As illustrated in the example of FIG. 1, the exemplary semiconductor module 1 can further comprise a second sub-unit 12 with a first contact element 31′ having a cooling function. The first contact element 31′ can comprise a first contact side 32. The second sub-unit 12 can comprise a third contact element 51 having a cooling function. The third contact element 51 can comprise a third contact side 52, and at least one semiconductor chip 2′. The at least one semiconductor chip 2′ has a first main electrode side 21 and a second main electrode side 22 opposite the first main electrode side 21. The at least one semiconductor chip 2′ can be thermally connected on its first main electrode side 21 to the first contact side 32, and can be thermally connected on its second main electrode side 22 to the third contact side 52. The semiconductor chip 2′ illustrated in the example of FIG. 1 can be, for example, a switch like an insulated gate bipolar transistor (IGBT), that comprises a gate electrode, which is electrically connected by a gate connection 28 to an electrical connector 29, which can be in the form of a lead frame, for example. A base plate 23 can be arranged on the first main electrode side 21 of the chip 2′, and a base plate 24 can be arranged on the second main electrode side 22. At least one electrical connection can be established between at least one semiconductor chip 2′ and the first or third contact side 32, 52. It is also possible for the second-unit 12 that, for example, at least one, but not all chips 2′ are electrically connected on the first main side 21 to the first contact side 32 and/or at least one, but not all chips 2′ are electrically connected on the second main electrode side 22 to the third contact side 52. Any conceivable combinations of electrical connections such as all chips 2′ of the second sub-unit 12 being electrically connected to the first and/or third contact side 32, 52, for example, are also possible. The second sub-unit 12 can comprise a second fixation means 7, which firmly connects the first and third contact element 31′, 51 together with the at least one semiconductor chip 2′. The second fixation means 7 can be a screw or a clamping device, for example. Springs or other types of flexible or compressible elements can be used to improve the contact between the contact elements 31′, 51, base plates 23, 24 and the chip 2′.

According to an exemplary embodiment, at least one first flexible element 33 can be arranged between the first contact element 31 of the first sub-unit 11 and the first contact element 31′ of the second sub-unit 12. The at least one first flexible element 33 can be electrically and thermally connected to the first contact element 31 of the first sub-unit 11 and to the first contact element 31′ of the second sub-unit 12. According to an exemplary embodiment the first flexible element 33 can be a cable strand, for example. A cable strand has the advantage in that it can achieve a good electrical connection and it has superior mechanical properties, i.e. it is stable, while also having flexibility properties.

According to another exemplary embodiment, a first cooling element 3 can comprise the first contact elements 31, 31′. The first cooling element 3 can also comprise cooling fins 34 to improve the cooling properties of the device. The first cooling element 3 comprising the first contact elements 31, 31′ and the flexible element 33 may be formed from one piece, e.g. by a diminution (e.g. by reducing the thickness or width) between the first contact elements 31, 31′. The configuration of the first flexible element 33 is not limited to these examples. The first flexible element 33 can be any possible type of structural configuration, a vertical movement or shifting of two first contact elements 31, 31′ against each other, in the case where contact elements 31, 31′ belong to one cooling element 3 but are part of two neighboured subunits 11 and 12, and it has appropriate electrical conductivity properties for current to flow between the contact elements 31, 31′. The flexible element 33 can, for example, comprise a bended or folded portion.

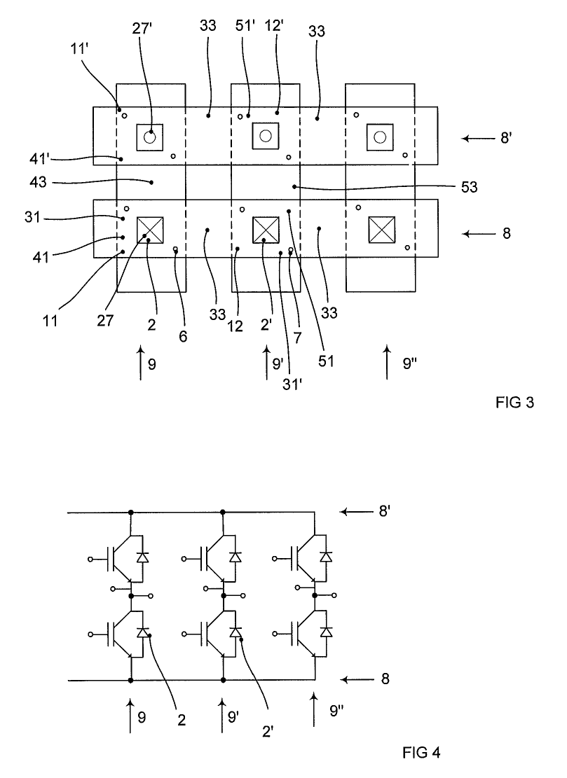

According to an exemplary embodiment, a second cooling element 4 can comprise the second contact elements 41, 41′ arranged in one line 9, and a third cooling element 5 can comprise the third contact elements 51, 51′ arranged in one line 9′ (FIG. 3). According to an exemplary configuration, the cooling elements 4, 5 can comprise cooling fins 34 to improve the cooling properties of the device.

According to an exemplary embodiment, any of the sub-units 11, 11′, 12, 12′ may comprise only one semiconductor chip 2, 2′, 2″ (e.g. a diode, reverse conducting switch, bidirectional switch, etc.) or more than one semiconductor chip 2, 2′, 2″ (e.g. a co-package of an IGBT with a diode, such as an antiparallel diode configuration, for example). A combination of different types of chips, or more than one chip of one type, or at least two chips as a staple in which one is on the other are also possible configurations.

According to another exemplary embodiment, the first fixation means 6 can be reversibly detachable from the first contact element 31, the at least one semiconductor chip 2 and/or the second contact element 41. The second fixation means 7 can also be a compression means, which can be reversibly detachable from the first contact element 31′, the at least one semiconductor chip 2′ and/or the third contact element 51. Such reversible fixation means 6, 7 could be, for example, screws or screws in combination with springs, clamping means, bolts, etc.

According to another exemplary embodiment, the first and/or second fixation means 6, 7 could be a bonding means, such as an application of a glue or solder, in which case the bonding means may not be reversibly attachable. It is also possible to use a combination of reversible and non-reversible fixation means, either by using them alternatively or by using them in combination (e.g. screw together with bonding).

If a bonding means is used or if an appropriate electrical and thermal connection can be achieved between the contact elements 31, 31′, 41, 41′, 51, 51′ and the chips 2, 2′ in an appropriate manner, the contact elements 31, 31′, 41, 41′, 51 51′ are not required to be stiff, but could alternatively be partially or completely flexible. For example, the first contact elements 31, 31′ and first flexible elements 33 could be made of the same material, and could be made of one contiguous piece.

According to an exemplary embodiment, the semiconductor chips 2, 2′ can be arranged in a plane. This plane can either be a flat plane or a curved plane, if it is advantageous for geometrical reasons.

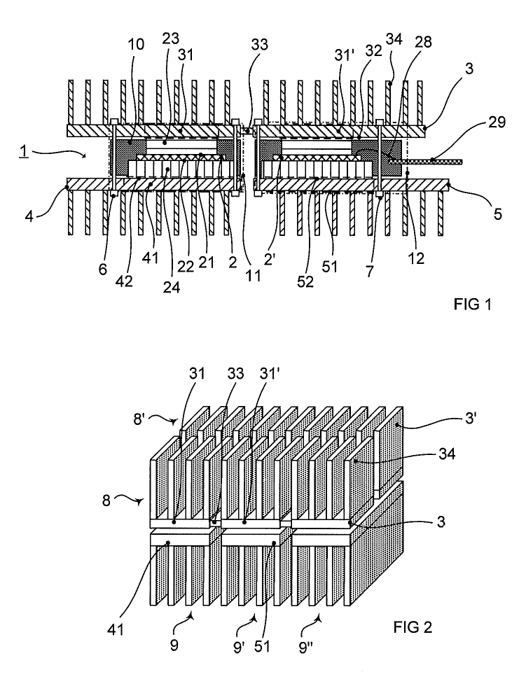

FIG. 2 shows a perspective view of an exemplary two-level-three-phase inverter with chips 2, 2′ being arranged in first lines 8, 8′ and second lines 9, 9′, 9″. The first line 8 can be an electrical connection for a positive voltage (e.g., DC+), and the first line 8′ can be an electrical connection for a negative or grounded voltage (e.g. DC−), for example. The second lines 9, 9′, 9″ can constitute the electrical connections for the three phases of an inverter, for example.

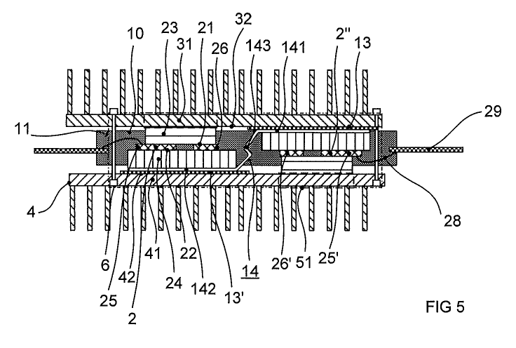

FIG. 3 shows a top view and FIG. 4 shows a schematic diagram of the exemplary two-level-three-phase inverter shown in FIG. 2. According to an exemplary embodiment, first sub-units 11, 11′ and second sub-units 12,12′ can be respectively arranged in a matrix with the sub-units or chips 2, 2′ being arranged in a first direction in first lines 8, 8′ and in a second direction in second lines 9, 9′, 9″. The crosses 27 and circles 27′ show the electrical conducting direction of the chips 2, 2′, where the crosses 27 indicate a direction from the first contact element 31 to the second contact element 41 and the circles indicate the opposite direction. In the exemplary embodiment shown in FIGS. 2 and 3, the first and second lines are arranged perpendicular to each other. A first sub-unit 11 can be arranged together with a second sub-unit 12 in a first direction in a first line 8 and another first sub-unit 11′ can be arranged together with another second sub-unit 12′ in the first direction in another first line 8′. The first sub-unit 11 and the first sub-unit 11′ can be arranged in a second direction in a second line 9, and the second sub-unit 12 and the second sub-unit 12′ can be arranged in the second direction in another second line 9′. An electrical connection can be established between the second contact element 41 of the first sub-unit 11 and the second contact element 41′ of the first sub-unit 11′. Alternatively or, in addition, an electrical connection can be established between the third contact element 51 of the second sub-unit 12 and the third contact element 51′ of the second sub-unit 12′.

FIG. 4 shows a schematic diagram of the exemplary two-level-three-phase inverter shown in FIG. 2. The semiconductor chips 2, 2′, which can be arranged in one second line 9, 9′ or 9″, are electrically connected in series.

Generally, chips within one line or within one sub-unit can be electrically connected in series, in parallel, in anti-parallel, or in any combination thereof.

With sub-units 11, 11′, 12, 12′ being arranged in a matrix as described above, different kind of inverters or converters can be built, such as a matrix converter or a three-level neutral point clamped inverter, for example.

In FIG. 3 it is shown that a second flexible element 43 may be arranged between the second contact element 41 of the first sub-unit 11 and the second contact element 41′ of the first sub-unit 11′, according to the example of FIG. 3 in which the sub-units 11, 11′ being arranged adjacent to each other in one second line 9. In this example, the second flexible element 43 can be electrically and thermally connected to the second contact elements 41, 41′. In the exemplary configuration illustrated in FIG. 3, a third flexible element 53 can also be arranged between the third contact element 51 of the second sub-unit 12 and the third contact element 51′ of the second sub-unit 12′, in which case the third flexible element 53 can be electrically and thermally connected to the third contact elements 51, 51′ of two neighboured sub-units 12, 12′.

It is not necessary that flexible elements 33, 43, 53 be arranged between all of the contact elements 31, 31′ or 41, 41′ or 51, 51′ belonging to sub-units, which are arranged in one line 8, 8′, 9, 9′, 9″. In the exemplary semiconductor module 1 according to at least one embodiment, a complete cooling element 4, 5, or 3 may be stiff, i.e. the cooling element does not have any flexible elements 33, 43, 53, and it is still possible to balance for different heights of all sub-units 11, 11′, 12, 12′ as long as there are enough flexible elements 33, 43, 53 available in the module 1, i.e. at least one flexible element 33. It is also possible to have in one line only some flexible elements 33 between two neighboured contact elements 31, 31′ or 41, 41′ or 51, 51′ and no flexible elements 33, 43, 53 between some other neighboured contact elements 31, 31′ or 41, 41′ or 51, 51′, in order to enhance the mechanical stiffness of the module 1 or for improved electrical conductivity.

FIG. 5 shows another exemplary embodiment of a first subunit 11 of the semiconductor module 1. The first subunit 11 comprises semiconductor chips 2, 2″, such as a number of gate controlled chips 25, 25″, including insulated gate bipolar transistors (IGBTs), and a number of diodes 26, 26′, for example. A gate controlled chip 25 and a diode 26 can be electrically and thermally connected to the first contact element 31 on their respective first main side 21. On the second main side of the chips 25, 26. The chips 25, 26 can be thermally connected to the second contact element 41 on their respective second main side 22. The chips 25, 26 can be electrically connected to each other on their second main side 22 via the base plate 24 and an electrical connector 142, which can be arranged between the chips 25, 26 and the second contact element 41. An insulation layer 13′ can be provided to insulate the electrical connector 142 from the second contact element 41. Generally, at least one electrical connection can be established between at least one semiconductor chip 2 on its first main electrode side 21 and the first contact side 32, and between the chip 2 on its second main electrode side 22 and an electrical connector 142.

Another chip 2″ or a set of gate controlled chip 25′ and diode 26′ can be arranged between the same first contact element 31 and the same second contact element 41, in which case the chips 2″ or 25′, 26′ can be thermally connected to the contact elements 31, 41. The chip 2″ or gate controlled chip 25′ and diode 26′ can be electrically connected to the second contact element 41 on their second main side 22. On the first main side 21 of the chips 25′, 26′, the chips 25′, 26′ are electrically connected to each other via base plate 23 and an electrical connector 141, which can be arranged between the chips 25′, 26′ and the first contact element 31. An insulation layer 13 can be provided to insulate the electrical connector 141 from the first contact element 31.

The electrical connector 141 can be electrically connected to the electrical connector 142 via a third flexible, electrically conductive element 143, which can be, for example, a spring between the electrical connectors 141, 142. The electrical connectors 141, 142 and the flexible connection element 143 can form a cross-over bar 14, as shown in the example of FIG. 5. According to an exemplary embodiment, the electrical connectors 141, 142 and the third flexible element 143 can be made from one piece. Of course, any type of semiconductor chips 2, 2′ or more or less semiconductor chips can be arranged in the prescribed manner. Thus, the exemplary embodiment is not to be limited to the illustrated configuration of (hips 25′, 26′).

In another exemplary embodiment, the semiconductor module 1 can comprise at least one sub-unit 11, 11′, 12, 12′ with a number of chips 2, 2′, 2″, all of which are electrically insulated on one main side 21, 22. The chips can be insulated from the first contact element 31 by an insulation layer 13, 13′ which is arranged between the first main side 21 and the first contact element 31. The chips can be electrically connected to each other by an electrical connector layer, which is arranged between the chips 2, 2′, 2″ on their first main electrode side 21 and the insulation layer 13, 13′. Alternatively, the chips can be insulated from the second contact element 41 by an insulation layer 13, 13′, which is arranged between the second main side 22 and the second contact element 41. In this example, the chips can be electrically connected to each other by an electrical connector layer, which is arranged between the chips 2, 2′, 2″ on their second main electrode side 22 and the insulation layer 13, 13′.

The semiconductor module according to the above-described exemplary embodiments can be applied in many electrical devices like a converter, inverter, motor drive, rectifier, power supply or a power factor controller, for example.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE LIST

1 Semiconductor module
11, 11′ first sub-unit
12, 12′ second sub-unit
13, 13′ insulation layer
14 cross-over bar
141 electrical connector
142 electrical connector
143 third flexible element
2, 2′, 2″ semiconductor chip
21 first main electrode side
22 second main electrode side
23, 24 base plate
25, 25′ gate controlled chips
26, 26′ diode
27, 27′ electrical conductivity direction
28 gate electrode
29 gate connection
3, 3′ first cooling element
31, 31′ first contact element
32 first contact side
33 first flexible element
34 cooling fins
4 second cooling element
41, 41′ second contact element
42 second contact side
43 second flexible element
5 third cooling element
51, 51′ third contact element
52 third contact side
53 third flexible element
6 first fixation means
7 second fixation means
8, 8′ first line
9, 9′ second line
10 insulator

What is claimed is:

1. A semiconductor module comprising:
a first sub-unit including a first contact element having a cooling function and a first contact side, a second contact element having a cooling function and comprising a second contact side, at least one semiconductor chip having a first main electrode side and a second main electrode side opposite to the first main electrode side, and a first fixation means for firmly connecting together the first and second contact elements of the first sub-unit and the at least one semiconductor chip of the first sub-unit, the at least one semiconductor chip of the first sub-unit being thermally connected to the first contact side on the first main electrode side of the at least one semiconductor chip of the first sub-unit, respectively, the at least one semiconductor chip of the first sub-unit being thermally connected to the second contact side on the second main electrode side of the at least one semiconductor chip of the first sub-unit, respectively, and at least one electrical connection being established between at least one semiconductor chip of the first sub-unit and the first or second contact side;
a second sub-unit including a first contact element having a cooling function and a first contact side, a third contact element having a cooling function and a third contact side, at least one semiconductor chip having a first main electrode side and a second main electrode side opposite to the first main electrode side, and a second fixation means for firmly connecting together the first and third contact elements of the second sub-unit and the at least one semiconductor chip of the second sub-unit, the at least one semiconductor chip of the second sub-unit being thermally connected to the first contact side of the second unit on the first main electrode side of the at least one semiconductor chip of the second sub-unit, respectively, the at least one semiconductor chip of the second sub-unit being thermally connected to the third contact side on the second main electrode side of the at least one semiconductor chip of the second sub-unit, and at least one electrical connection being established between at least one semiconductor chip of the second sub-unit and the first or third contact side of the second sub-unit; and
at least one first flexible element, which is arranged between the first contact element of the first sub-unit and the first contact element of the second sub-unit,
wherein at least one of the at least one first flexible element is electrically and thermally connected to the first contact element of the first sub-unit and to the first contact element of the second sub-unit, and
wherein the first sub-unit and the second sub-unit are individually compressed by the first fixation means and the second fixation means, respectively.

2. The semiconductor module according to claim 1, wherein at least one electrical connection is established between at least one semiconductor chip and the first contact side in the first sub-unit, and at least one electrical connection is established between at least one semiconductor chip and the second contact side in the first sub-unit.

3. The semiconductor module according to claim 1, wherein at least one electrical connection is established between at least one semiconductor chip and the first contact side in the second sub-unit, and at least one electrical connection is established between at least one semiconductor chip and the third contact side in the second sub-unit.

4. The semiconductor module according to claim 1, wherein at least one semiconductor chip in the first sub-unit and at least one semiconductor chip in the second sub-unit are arranged in a plane.

5. The semiconductor module according to claim 4, wherein the plane is flat.

6. The semiconductor module according to claim 4, wherein the plane is curved.

7. The semiconductor module according to claim 1, wherein the first contact element of the first sub-unit, the first contact element of the second sub-unit and the at least one first flexible element are formed in one piece.

8. The semiconductor module according to claim 1, wherein the at least one first flexible element is a cable strand.

9. The semiconductor module according to claim 1, wherein:
the first sub-unit comprises at least two semiconductor chips;
at least one electrical connection is established between the first contact side of the first sub-unit and the first main electrode side of at least one semiconductor chip of the first sub-unit, respectively, and between a first electrical connector and the second main electrode surface of said at least one semiconductor chip of the first sub-unit;
the first sub-unit comprises a first insulation layer arranged between and electrically insulating the first electrical connector and the second contact element of the first sub-unit;
at least one electrical connection is established between the second contact side of the first sub-unit and the second main side of at least one other semiconductor chip of the first sub-unit, respectively, and between a second electrical connector and the first main surface of said at least one semiconductor chip of the first sub-unit;
the first sub-unit comprises a second insulation layer arranged between and electrically insulating the second electrical connector of the first sub-unit and the first contact element of the first sub-unit; and
the first sub-unit comprises a third flexible element configured to electrically connect the first and second electrical connectors to each other.

10. The semiconductor module according to claim 1, wherein:
the first sub-unit is arranged together with the second sub-unit in a first direction in a first line, and another first sub-unit is arranged together with another second sub-unit in the first direction in another first line;
the first sub-unit and the another first sub-unit are arranged in a second direction in a second line, and the second sub-unit and the another second sub-unit are arranged in the second direction in another second line;
an electrical connection is established between at least one of
the second contact element of the first sub-unit and the second contact element of the first sub-unit, and
the third contact element of the second sub-unit and the third contact element of the another second sub-unit.

11. The semiconductor module according to claim 10, comprising a second flexible element arranged between the second contact element of the first sub-unit and the second contact element of the first sub-unit, the second flexible element being electrically and thermally connected to the second contact elements of the first and second sub-units.

12. The semiconductor module according to claim 10, wherein at least one of (a) the first contact elements of the first and second sub-units are arranged in one first line to form a stiff first cooling element, (b) the second contact elements of the first and second sub-units are arranged in one second line to form a stiff second cooling element, and (c) the third contact elements of the second sub-unit and the another second sub-unit are arranged in one second line to form a stiff third cooling element.

13. The semiconductor module according to claim 1, wherein the first fixation means is reversibly detachable from at least one of the first contact element of the first sub-unit, the at least one semiconductor chip of the first sub-unit and the second contact element of the first sub-unit.

14. The semiconductor module according to claim 1, wherein at least one of the first fixation means and the second fixation means is a compression instrument and/or a bonding instrument.

15. The semiconductor module according to claim 1, wherein the semiconductor module is configured to be applied in at least one of a converter, inverter, motor drive, rectifier, power supply, and power factor controller.

16. The semiconductor module according to claim 10, comprising a third flexible element arranged between the third contact element of the second sub-unit and the third contact element of another second sub-unit, the third flexible element being electrically and thermally connected to said third contact elements of the second sub-unit and the another second sub-unit.

17. The semiconductor module according to claim 11, comprising a third flexible element arranged between the third contact element of the second sub-unit and the third contact element of another second sub-unit, the third flexible element being electrically and thermally connected to said third contact elements of the second sub-unit and the another second sub-unit.

18. The semiconductor module according to claim 1, wherein the second fixation means is reversibly detachable from at least one of the first contact element of the second sub-unit, the at least one semiconductor chip of the second sub-unit, and the third contact element of the second sub-unit.

19. The semiconductor module according to claim 13, wherein the second fixation means is reversibly detachable from at least one of the first contact element of the second sub-unit, the at least one semiconductor chip of the second sub-unit, and the third contact element of the second sub-unit.

20. The semiconductor module according to claim 14, wherein the bonding instrument is at least one of glue and solder.

21. A semiconductor module comprising:
a first sub-unit including a first contact element having a first contact side, a second contact element having a second contact side, at least one semiconductor chip having a first main electrode side and a second main electrode side opposite to the first main electrode side, and a first fixation means for firmly connecting together the first and second contact elements of the first sub-unit and the at least one semiconductor chip of the first sub-unit;
a second sub-unit including a first contact element having a first contact side, a third contact element having a third contact side, at least one semiconductor chip having a first main electrode side and a second main electrode side opposite to the first main electrode side, and a second fixation means for firmly connecting together the first and third contact elements of the second sub-unit and the at least one semiconductor chip of the second sub-unit; and
at least one first flexible element, which is arranged between the first contact element of the first sub-unit and the first contact element of the second sub-unit,
wherein at least one of the at least one first flexible element is electrically and thermally connected to the first contact element of the first sub-unit and to the first contact element of the second sub-unit, and
wherein the first sub-unit and the second sub-unit are individually compressed by the first fixation means and the second fixation means, respectively.

22. The semiconductor module according to claim 21, wherein at least one electrical connection is established between at least one semiconductor chip and the first contact side in the first sub-unit, and at least one electrical connection is established between at least one semiconductor chip and the second contact side in the first sub-unit.

23. The semiconductor module according to claim 21, wherein at least one electrical connection is established between at least one semiconductor chip and the first contact side in the second sub-unit, and at least one electrical connection is established between at least one semiconductor chip and the third contact side in the second sub-unit.

24. The semiconductor module according to claim 21, wherein the first contact element of the first sub-unit, the first contact element of the second sub-unit and the at least one first flexible element are formed in one piece.

25. The semiconductor module according to claim 21, wherein the at least one first flexible element is a cable strand.
